(19) United States
(12) Patent Application Publication
(10) Pub. No.: US 2007/0238309 A1
(43) Pub. Date: Oct. 11, 2007

(54) Method of reducing interconnect line to line capacitance by using a low k spacer

(76) Inventors: Jun He, Portland, OR (US); Kevin J. Fischer, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/394,913

(22) Filed: Mar. 31, 2006

(51) Int. Cl. H01L 21/31; H01L 21/469

(52) U.S. Cl. 438/758

(57) ABSTRACT

A method is described of reducing the line to line capacitance within semiconductor devices and a device demonstrating the same. The device includes a spacer layer disposed between an etch stop material and a conductive layer. Separating the etch stop layer from the conductive layers by the spacer layer may decrease the line to line capacitance significantly in a semiconductor device.

### FIELD

Embodiments of the invention relate generally to semiconductor processing, and, more specifically, to a method of reducing interconnect line to line capacitance by using a low k spacer.

### BACKGROUND

The performance of some semiconductor devices may suffer from back end line to line capacitance due to adjacent layers within the device, such as a hermetic etch stop and a metal layer. Currently, line to line capacitance is reduced by reducing the dielectric constant of the etch stop layer or by reducing the dielectric constant of the inter layer dielectric. Reducing the dielectric constant of the etch stop layer may be achieved by reducing the etch stop layer's density, which makes the film less hermetic and compromises the etch stop layer as an adequate copper diffusion barrier. Reducing the dielectric constant of the inter layer dielectric may require re-engineering the entire back end with substantial integration challenges and reliability risks due to poor chemical and mechanical stability of low k dielectric materials.

### BRIEF DESCRIPTION OF THE DRAWINGS

Embodiments of the present invention are illustrated by way of example and not limitation in the figures of the accompanying drawings, in which like references indicate similar elements, and in which:

FIG. 1 is a cross-sectional illustration of the back end of a semiconductor device featuring conductive layers, capping layers, a spacer layer, and an etch stop layer according to an embodiment of the present invention.

FIG. 2 is a cross-sectional illustration of the back end of a semiconductor device featuring conductive layers, capping layers, and a spacer/etch stop composite layer according to an embodiment of the present invention.

FIG. 3 is a flowchart of two methods of forming embodiments of the present invention.

FIG. 4A-4F is a method of forming a semiconductor device which includes capping layers, a spacer layer, and an etch stop layer according to an embodiment of the present invention.

FIG. 5A-5D is a method of forming a semiconductor device which includes capping layers, a spacer layer, and an etch stop layer according to an embodiment of the present invention.

### DETAILED DESCRIPTION

Embodiments of devices that feature low k spacers to reduce interconnect line to line capacitance as well as methods for fabricating such devices.

As described in more detail below, a spacer layer disposed between a conductive layer and an etch stop layer to reduce interconnect line to line capacitance in the backend of a semiconductor device. The spacer layer may aid the etch stop layer provide a hermetic seal for the conductive layers from external elements and materials. However, the spacer layer may function adequately without a relative high dielectric constant as needed for the etch stop layer. A composite layer, comprising material properties of the spacer and etch stop layer, may replace the individual spacer and etch stop layers to adequately seal the conductive layers and reduce interconnect line to line capacitance.

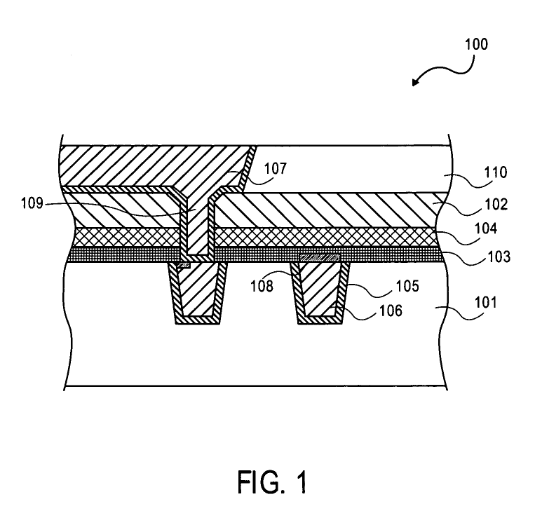

FIG. 1 is a cross-sectional illustration of a semiconductor device according to an embodiment of the present invention. As illustrated, device 100 includes first, second, and third regions of dielectric material 101, 102, 110, via 109, first and second conductive layers 106, 107, and adhesion layers 105. First, second, and third regions of dielectric material 101, 102, 110 may comprise silicon dioxide, silicon nitride, or any material that is nonconductive of electric current. First, second, and third regions of dielectric material 102, 102, 110 may comprise the same material or may comprise different materials. First and second conductive layers 106, 107 are embedded in first and second regions of dielectric material and may allow the transmission of electric currents in device 100. First and second conductive layers 106, 107 may comprise copper, aluminum, or any material capable of allowing the transmission of electric currents. Adhesions layers 105 may surround a portion of the perimeter of first and second conductive layers 106, 107 to isolate the conductive material from first, second, and third regions dielectric material 102, 102, 110. Adhesion layers 105 may comprise titanium, titanium nitride, or any material from which first and second conductive layers 106, 107 may adhere to.

FIG. 1 also illustrates capping layers 108 disposed on first conductive layers 106 according to an embodiment of the present invention. In an embodiment, capping layers 108 may improve metal electro-migration of the conductive material of conductive layers 106. For example, when first conductive layers 106 comprises copper, capping layers 108 may improve the diffusion of copper within the area defined for first conductive layers 106 in device 100. Capping layers 108 may also function to contain the top perimeter of first conductive layers 106, preventing the interaction with subsequent patterned layers adjacent or proximate to first conductive layers 106. Capping layers 108 may have a cross-sectional thickness in the range of 5-100 nanometers to adequately contain the top perimeter of first conductive layers 106 and in an embodiment, capping layers 108 may have a cross-sectional thickness of 50 nanometers. Capping layers 108 may comprise any material capable of containing the top perimeter of first conductive layers 106. For example, capping layers 108 may comprise a refractory material such as, but not limited to, tungsten, titanium, tantalum, or hafnium. In an embodiment, capping layers 108 comprise tungsten.

An etch stop layer 104 may be disposed over first conductive layers 106 within device 100 according to an embodiment of the present invention. Etch stop layer 104 may function within device 100 to serve as an etch barrier during the patterning of a conductive layer such as first conductive layers 106. Etch stop layer 104 may also function as a hermetic seal that prevents the materials above etch stop layer 104 from exposure to the materials beneath. In an embodiment, the density of etch stop layer 104 should be adequate to seal first conductive layers 106, from exposure to other materials, moisture, or external elements. The density of most materials, such as etch stop layer 104, correlates with their dielectric constant property. For example, a material that has a high density will usually have a high dielectric constant and a material that has a low density will typically have a low dielectric constant. Likewise, etch stop layer 104 has a high dielectric constant such that the dielectric constant is approximately equal to or greater than 4.5. In an embodiment, the dielectric constant of etch stop layer 104 is approximately equal to 4.5.

Etch stop layer 104 may comprise any material with a dielectric constant greater than 4.5 such as silicon nitride, carbon doped silicon nitride, silicon carbide, or nitrogen doped silicon carbide. In an embodiment, etch stop layer 104 comprises silicon carbide. Etch stop layer 104 must also have an adequate thickness to serve as an etch barrier during conductive layer formation and or seal the conductive layers from the surrounding elements. Etch stop layer 104 may have a thickness within the range of 7.5-100 nanometers. In an embodiment, etch stop layer 104 has a thickness approximately equal to 25 nanometers.

A spacer layer 103 may be disposed on capping layers 108, conductive layer 106, and first region of dielectric material 102 as further illustrated in FIG. 1. Spacer layer 103 may separate etch stop layer 104 from first conductive layers 106 which may decrease the line to line capacitance within device 100 according to an embodiment of the present invention. Spacer layer 103 may have any thickness suitable to significantly reduce the line to line capacitance within device 100. For example, the thickness of spacer layer 103 may range from 50-100 nanometers. In an embodiment, the thickness of spacer layer 103 is approximately 50 nanometers. Spacer layer 103 must not be too thick such that etch stop layer 104 is close enough to second conductive layer 107 to induce line to line capacitance within device 100.

Spacer layer 103 may comprise any material suitable to separate etch stop layer 104 and conductive layers 106 such as silicon dioxide, silicon nitride, carbon doped oxide, or a fluorine doped oxide and in an embodiment, spacer layer 103 comprises a carbon doped oxide material. Spacer layer 103 may also aid etch stop layer 104 seal first conductive layers 106 from exposure to adjacent materials. The dielectric constant of spacer layer 103 may not be as high as the dielectric constant of etch stop layer 104, however, conductive layers 106 may be adequately sealed due to the aid of etch stop layer 104. For example, the dielectric constant of spacer layer 103 may be approximately 3.9 or less and in an embodiment, the dielectric constant of spacer layer 103 may be approximately equal to 3.9.

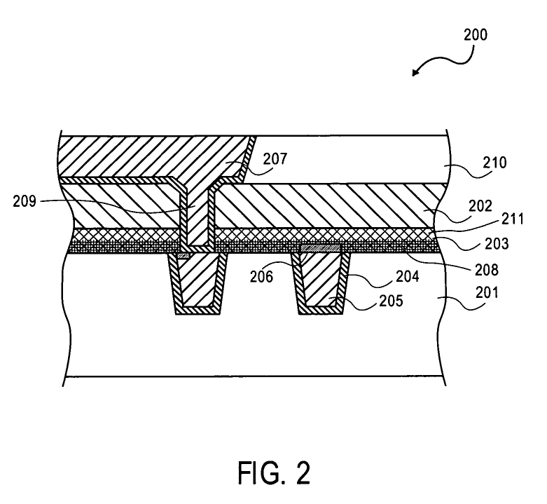

In an embodiment as illustrated in FIG. 2, device 200 has a composite layer 203 that includes a gradient of a spacer and etch stop material. In an embodiment, a spacer portion 208 of composite layer 203 is adjacent to capping layers 206 and a etch stop portion 211 is adjacent to second conductive layer 207. In an embodiment, composite layer 203 may serve the dual purpose of spacer layer 103 and etch stop layer 104. Composite layer 203 may have a cross-sectional thickness that is suitable to serve as a barrier during copper formation, substantially seal first conductive layers 205, and separate etch stop portion 211 from first conductive layers 205 to decrease the line to line capacitance within device 200. For example, the thickness of composite layer 203 may range from approximately 60-200 nanometers. In an embodiment, the thickness of composite layer 203 is approximately 100 nanometers. Along with composite layer 203, device 200 further comprises first, second, and third regions of dielectric material 201, 202, 210, first and second conductive layers 205, 207, adhesion layers 204, capping layers 206, and via 209.

There may be many distributions of etch stop portion 211 and spacer portion 208 within composite layer 203. For example, the distribution of etch stop portion 211 may range from 30 to 70% within composite layer 203. In an embodiment, the distribution of etch stop portion 211 and spacer portion 208 is approximately 70% and 30% respectively.

Composite layer 203 may also have a gradient of material characterized by the materials' dielectric constant property. For example, etch stop portion 211 may have a dielectric constant greater than or equal to 4.5 and spacer portion 208 may have a dielectric constant less than or equal to 3.9 and in an embodiment, the dielectric constant of etch stop portion 211 is approximately equal to 4.5 and the dielectric constant of spacer portion 208 is approximately equal to 3.9.

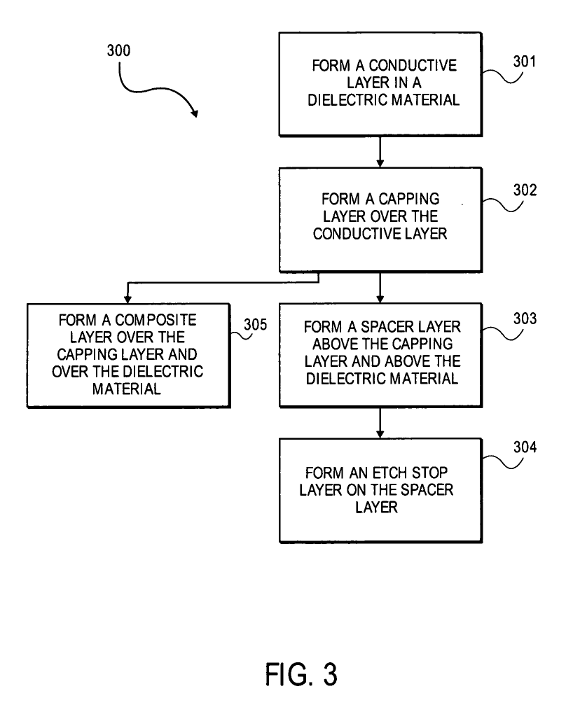

In an embodiment of the present invention, device 100 may be manufactured by any suitable process such that device 100 includes spacer layer 103 and etch stop layer 104 disposed over first conductive layers 106. In an embodiment as illustrated in FIG. 3, device 100 may be formed by one of the two processes shown in flowchart 300. The first process may be defined in flowchart 300 as including steps 301, 302, 303, and 304 and a second process may be defined as including steps 301, 302, and 305.

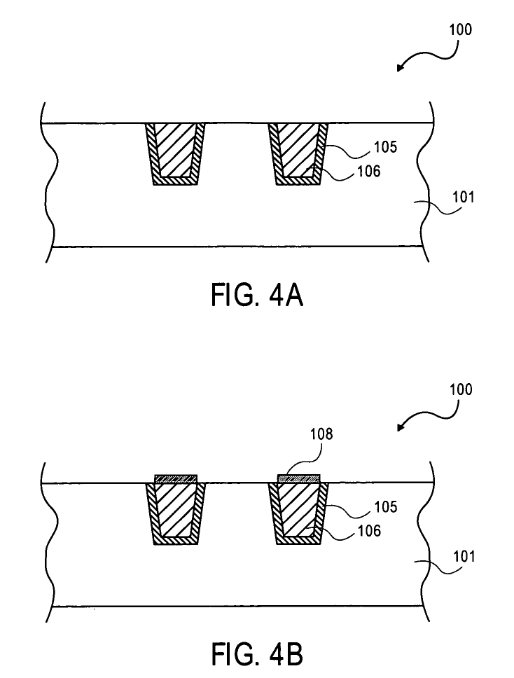

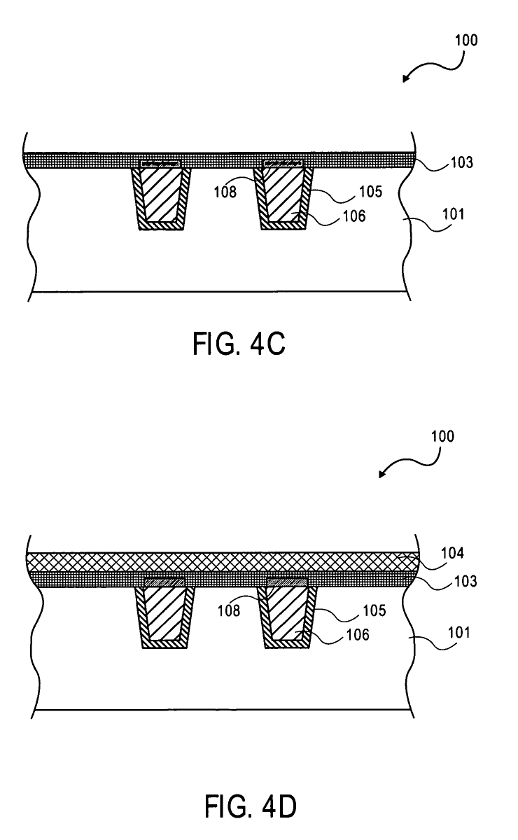

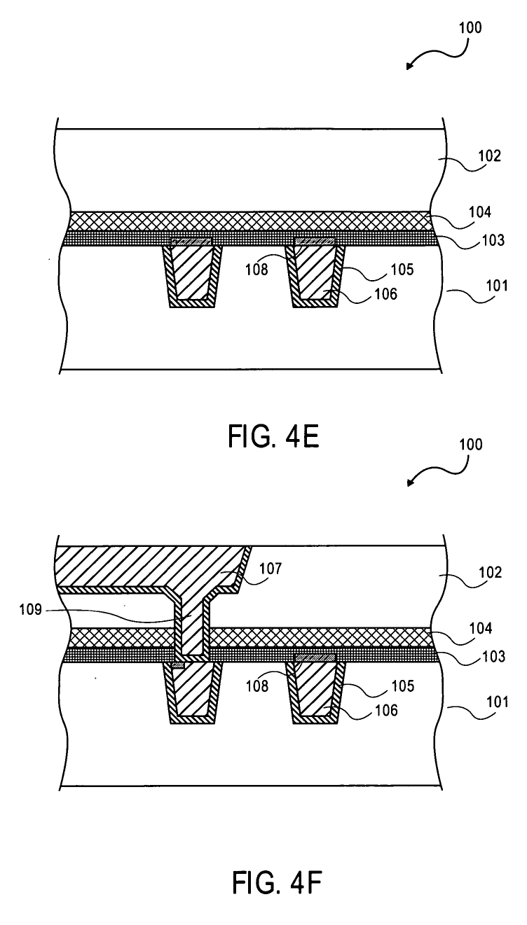

In an embodiment as illustrated in FIGS. 4A-4F, device 100 may be manufactured according to the first process defined in flowchart 300. FIG. 4A illustrates the beginning of the first process defined in flowchart 300 which shows a first region of dielectric material 101. In an embodiment, first region of dielectric material 101 may comprise silicon dioxide or any dielectric material capable of isolating electrically conductive material. In an embodiment, first region of dielectric material 101 may be formed by a deposition process such as, but not limited to, chemical vapor deposition (CVD), plasma enhanced chemical vapor deposition (PECVD), or high density plasma chemical vapor deposition (HDP CVD). Disposed within first region of dielectric material 101 are adhesive layers 105 and first conductive layers 106 according to an embodiment.

Adhesion layers 105 and conductive layers 106 may be manufactured by any method known in the art. For example, adhesion layers 105 may be formed by evaporation, sputtering, or a CVD process. Conductive layers 106 may be formed by a subtractive etch or a damascene process. In an embodiment, adhesion layers 105 are formed by sputtering and conductive layers 106 are formed by a damascene process.

Next, in an embodiment illustrated in FIG. 4B, capping layers 108 are formed on first conductive layers 106. Capping layers 108 may be formed by any suitable process known in the art such as, but not limited to, evaporation, sputtering, or an electro-less deposition process and in an embodiment, capping layers 108 may be formed by an electro-less deposition process such that capping layers 108 are formed primarily on first conductive layers 106 and are not formed on first region of dielectric material 101.

A spacer layer 103 may be formed over capping layers 108, first region of dielectric material 101, adhesive layers 105, and first conductive layers 106 as illustrated in FIG. 4C. Spacer layer 103 may be formed by evaporation, sputtering, or a CVD process and in an embodiment, spacer layer 103 may be formed by a CVD process.

Next, in an embodiment illustrated in FIG. 4D, etch stop layer 104 may be formed on spacer layer 103. Etch stop layer 104 may be formed by any suitable process known in the art such as, but not limited to, rapid thermal processing or chemical vapor deposition. In an embodiment, etch stop layer 104 is formed by a chemical vapor deposition process such that approximately 25 nanometers of etch stop layer 104 is disposed over spacer layer 103.

A plurality of conductive layers may be formed within device 100. In an embodiment, second region of dielectric material 102 may be formed over etch stop layer 104. Second region of dielectric material 102 may be formed by process techniques similar to those used to form first region of dielectric material 101 and in an embodiment, second region of dielectric material 102 is formed by a CVD process.

Next, as illustrated in FIG. 4F, a second conductive layer 107 may be formed in second region of dielectric material 102 and in an embodiment, second conductive layer 107 may be formed in second region of dielectric material 102 by a damascene process. As illustrated in FIG. 4F, first a via 109 is formed in second region of dielectric material 102. Via 109 may be formed by etching an opening through second region of dielectric material 102 to the top surface conductive layers 106 such that a portion of capping layer 108 may be etched as illustrated. In an embodiment, an adhesive layer 105 is formed in via 109 and subsequently a conductive material is formed in the remaining area of via 109. Via 109 may comprise any material capable of electrically coupling first and second conductive layers 106, 107 such as, but not limited to, tungsten.

In an embodiment, a third region of dielectric material 110 is formed over via 109 and second region of dielectric material 102. In an embodiment, third region of dielectric material 110 may be formed by similar process techniques used to form first and second regions of dielectric material 106, 107 and in an embodiment, third region of dielectric material 110 may be formed by a chemical vapor deposition process.

After third region of dielectric material 110 is formed, second conductive layer 107 may be formed within by a damascene process. After formation in third region of dielectric material 109, second conductive layer 107 may be planarized by a chemical mechanical polishing technique.

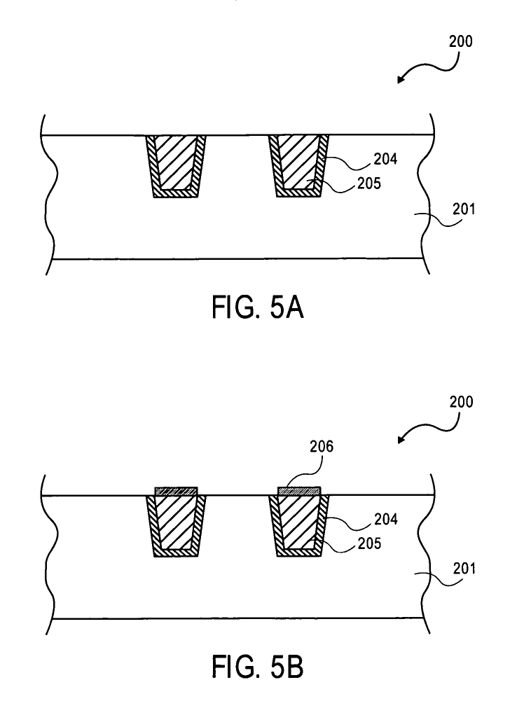

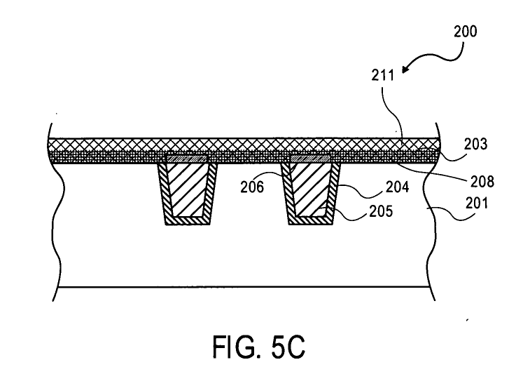

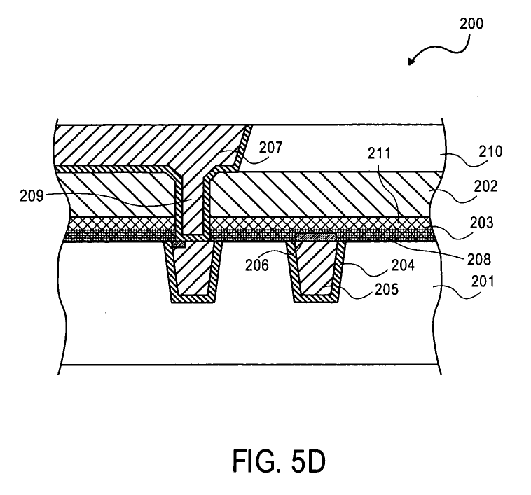

Device 200 may be manufactured by the second process defined in flowchart 300 in FIGS. 5A-5D. FIGS. 5A-5B are substantially similar to FIGS. 4A-4B and they illustrate the formation of first region of dielectric material 101, adhesion layers 105, first conductive layer 106, and capping layers 108.

However as illustrated in FIG. 5C, the second process diverges from the first process in that a composite layer 203 is formed, comprising an etch stop portion 211 and a spacer portion 208, over capping layers 108. Composite layer 203 may be formed by any suitable process such that composite layer 203 comprises a gradient of etch stop and spacer material. Composite layer 203 may be formed by a rapid thermal processing technique. For example, in a RTP chamber, carbon and silicon dioxide may be introduced to device 200 such that a carbon doped oxide material is formed as spacer portion 208. After spacer portion 208 is formed, oxygen gas may be removed from the chamber such that a silicon carbide material is formed, as etch stop portion 202, over spacer portion 208.

After composite layer 203 is formed, the second process defined in flowchart 300 converges with that of the first process. As illustrated in FIG. 5D, adhesion layers 204, second and third regions of dielectric material 202, 210, second conductive layer 207, and via 209 are subsequently formed.

In the foregoing specification, specific exemplary embodiments of the invention have been described. It will, however, be evident that various modifications and changes may be made thereto. The specification and drawings are, accordingly, to be regarded in an illustrative rather than a restrictive sense.

What is claimed is:

1. A device comprising:
a first conductive layer;
a capping layer disposed on said first conductive layer;
a spacer layer disposed on said capping layer; and
an etch stop layer disposed on said spacer layer.

2. The device of claim 1, wherein said capping layer is disposed substantially on said first conductive layer.

3. The device of claim 1, wherein the cross-sectional thickness of said capping layer is in the range from 5 nm to 100 nm.

4. The device of claim 1, wherein said spacer layer has a dielectric constant value less than or equal to 3.9.

5. The device of claim 1, wherein said spacer layer is selected from the group consisting of silicon dioxide, carbon doped oxide, silicon nitride, and fluorine doped oxide.

6. The device of claim 1, wherein the cross-sectional thickness of said spacer layer is in the range from 50 nm to 100 nm.

7. The device of claim 1, wherein said etch stop layer has a dielectric constant value greater than or equal to about 4.5.

8. The device of claim 1, wherein said etch stop layer is selected from the group consisting of silicon nitride, carbon doped silicon nitride, silicon carbide, and nitrogen doped silicon carbide.

9. The device of claim 1, wherein the cross-sectional thickness of said etch stop layer is in the range from 7.5 nm to 100 nm.

10. A device comprising:
a first conductive layer; and
a composite layer disposed on said first conductive layer wherein said composite layer comprises a gradient of a first material and a second material wherein said dielectric constant of said first material is less than the dielectric constant of said second material.

11. The device of claim 10, wherein said first material portion of said composite layer is adjacent to said first conductive layer.

12. The device of claim 10, wherein said composite layer comprises a substantially equal distribution of said first material and said second material.

13. The device of claim 10, wherein said first material has a dielectric value less than or equal to 3.9 and said second material has a dielectric value greater than or equal to 4.5.

14. The device of claim 10, wherein the cross-sectional thickness of said composite layer is approximately 60 nm.

15. A method comprising:
forming a first conductive layer in a first region of dielectric material; and
forming a composite layer on said first conductive layer wherein said composite layer comprises a gradient of a first material and a second material.

16. The method of claim 15 further comprises forming a capping layer after forming said conductive layer and prior to forming said composite layer.

17. The method of claim 15, wherein forming said capping layer comprises an electro-less deposition process.

18. The method of claim 15, wherein said first material and said second material are formed by a chemical vapor deposition process.

19. The method of claim 15, wherein said first material and said second material are formed in a single deposition chamber.

20. The method of claim 15, wherein said gradient comprises a greater portion of said first material than said second material.
